(19) United States
(12) Patent Application Publication
(10) Pub. No.: US 2008/0251882 A1
(43) Pub. Date: Oct. 16, 2008

(54) Semiconductor device and method of fabricating the same

(76) Inventor: Tatsuhiko KOIDE, Mizuho-shi (JP)

Correspondence Address: MCDERMOTT WILL & EMERY LLP, 600 13TH STREET, N.W., WASHINGTON, DC, 20005-3096, US

(21) Appl. No.: 12/078,309

(22) Filed: Mar. 28, 2008

(30) Foreign Application Priority Data
Mar. 30, 2007 (JP) JP2007-090330

(51) Int. Cl. H01L 29/00; H01L 21/76

(52) U.S. Cl. 257/509; 438/440; 257/E21.54

(57) ABSTRACT

A semiconductor device includes a first insulating isolation film provided on a main surface of a semiconductor substrate, an active region surrounded by the first insulating isolation film, and a second insulating isolation film provided on the main surface of the semiconductor substrate, having a thickness smaller than that of the first insulating isolation film and separating the active region into a first active region and a second active region.

### CROSS-REFERENCE TO RELATED APPLICATIONS

The priority application number JP2007-090330, Semiconductor Device and Method of Fabricating the Same, Mar. 30, 2007, Tatsuhiko Koide, upon which this patent application is based is hereby incorporated by reference.

### BACKGROUND OF THE INVENTION

1. Field of the Invention

The present invention relates to a semiconductor device and a method of fabricating the same.

2. Description of the Background Art

As portable electronic apparatuses such as a cellular phone, a personal digital assistance (PDA), a digital video camera (DVC), and a digital steel camera (DSC) have sophisticated, a system LSI attaining high integration and speeding up is demanded. Japanese Patent Laying-Open No. 2002-16077 discloses a heterojunction bipolar transistor in which a base layer is made of silicon germanium (SiGe) as a module attaining the high speed operational system LSI.

A structure of a bipolar transistor (semiconductor device) described in Japanese Patent Laying-Open No. 2002-16077 will be described with reference to FIG. 11. FIG. 11 is a schematic sectional view showing a main structure of a conventional semiconductor device.

In the conventional semiconductor device, an epitaxial film made of N-type silicon is stacked on a P-type silicon semiconductor substrate 101, thereby forming a collector region 112. An N-type buried layer 112a is provided between the collector region 112 and the semiconductor substrate 101 and functions as a conductive path of the collector region. Element isolation layers 105 by a LOCOS (local oxidation of silicon) method is formed on a part of the collector region 112, and a main surface S of the collector region 112 are insulatingly separated into two active regions 106 and 107 of silicon exposed. A collector pull-out portion 108 implanted with a high-concentration N-type impurity is formed on one of the active regions 106 and 107 (active region 106), while a base region 103 and an emitter region 104 are formed on the other (active region 107). A collector electrode, a base electrode and an emitter electrode are electrically connected to the collector pull-out portion 108, the base region 103 and the emitter region 104 respectively, thereby forming the bipolar transistor (semiconductor device).

In general, a film is formed on the semiconductor substrate 101 by employing epitaxial technique for forming the collector region 112. However, this film formation by epitaxial technique is inefficient in productivity and hence contributes to increase in a manufacturing cost of the semiconductor device. A method of forming the collector region 112 by implanting the N-type impurity into the semiconductor substrate 101 provided with the element isolation layers 105 by the LOCOS method is employed in order to suppress such increase in the manufacturing cost and improve a low cost of the semiconductor device.

FIG. 12 is a schematic sectional view of the semiconductor device formed with the collector region by ion implantation. According to the ion implantation, the collector region 112 having the concentration distribution of an N-type impurity in a depth direction from the main surface S is formed and a high concentration layer 112a having the particularly high concentration of the N-type impurity is formed around a position where the concentration of the N-type impurity reaches a peak. This high concentration layer 112a corresponds to the aforementioned N-type buried layer 112a (see FIG. 11), which is a main conductive path inside the collector region 112 in the emitter-collector conduction.

In order to perform ion implantation through the element isolation layers 105 by the LOCOS method, the depth (peak depth) from the main surface S to the position where the N-type impurity concentration in the collector region 112 reaches a peak, located immediately under the element isolation layers 105 is different from that from the main surface S to the position where the N-type impurity concentration in the collector region 112 reaches a peak, under the active regions 106 and 107. More specifically, a peak depth p1 located immediately under the element isolation layers 105 is so formed as to be shallower than a peak depth p0 located immediately under the active regions 106 and 107. The distribution position of the high concentration layer 112a in the collector region 112 from the main surface S, located immediately under the element isolation layers 105 is also shallower than that of the high concentration layer 112a in the collector region 112 from the main surface S, located immediately under the active regions 106 and 107.

According to this structure, however, the base region 103 and the high concentration layer 112a are closely-situated in the vicinity of a side surface (side closer to the active region 107) of the element isolation layer 105 insulatingly separated between the active regions 106 and 107, shown by dotted lined circle X in FIG. 12. In other wards, the N-type impurity concentration in the vicinity of the side surface of the element isolation layer 105 heightens and parasitic capacitance (junction capacitance) between the collector and the base is increased.

As a measure for the above, on the other hand, the peak depth p1 located immediately under the element isolation layers 105 is adjusted to the peak depth p0 identical with the conventional depth, whereby increase in the parasitic capacitance between the collector and the base can be suppressed. In this case, however, the peak depth located immediately under the active region 107 is situated at a deeper position and the distance from the emitter region 104 to the high concentration layer 112a is increased. Thus, a transport time of electrons flowing from a side of the emitter region to the collector region is increased, thereby causing reduction in the operating speed of a transistor.

Therefore, in the conventional bipolar transistor (semiconductor device) in which the collector region is formed by ion implantation, the parasitic capacitance between the collector and the base is disadvantageously increased due to the element isolation layer by the LOCOS method.

### SUMMARY OF THE INVENTION

The present invention has been proposed in order to solve the aforementioned problem, and an object of the present invention is to provide a semiconductor device capable of suppressing increase in the parasitic capacitance between a collector and a base and a method of fabricating the same.

In order to attain the aforementioned object, a semiconductor device according to the present invention comprises a first insulating isolation film provided on a main surface of a semiconductor substrate, an active region surrounded by the first insulating isolation film, a second insulating isolation film provided on the main surface of the semiconductor substrate, having a thickness smaller than that of the first insulating isolation film and separating the active region into a first active region and a second active region, an impurity layer formed on the first active region, a base region formed on the second active region and an emitter region on the base region, and a collector region formed on the semiconductor substrate.

In order to attain the aforementioned object, a method of fabricating a semiconductor device according to the present invention comprises steps of forming a first insulating isolation film comparting an active region and a second insulating isolation film having a thickness smaller than that of the first insulating isolation film and separating the active region into a first active region and a second active region on a main surface of a semiconductor substrate, implanting ions into the semiconductor substrate formed with the first insulating isolation film and the second insulating isolation film and forming a collector region, forming an impurity layer on the first active region, and forming a base region on the second active region and an emitter region on the base region.

According to the present invention, the semiconductor device capable of suppressing increase in the parasitic capacitance between the collector and the base and a method of fabricating the same can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of a semiconductor device according to an embodiment;

FIGS. 2 to 10 are a schematic sectional view of a step of fabricating the semiconductor device according to this embodiment;

FIG. 11 is a schematic sectional view showing a main structure of a conventional semiconductor device; and

FIG. 12 is a schematic sectional view of a semiconductor device in which a collector region is formed by ion implantation.

### DESCRIPTION OF THE PREFERRED EMBODIMENTS

An embodiment of the present invention will be hereinafter described with reference to the drawings. Similar components are denoted by similar reference numerals in all drawings to omit a detailed description thereof.

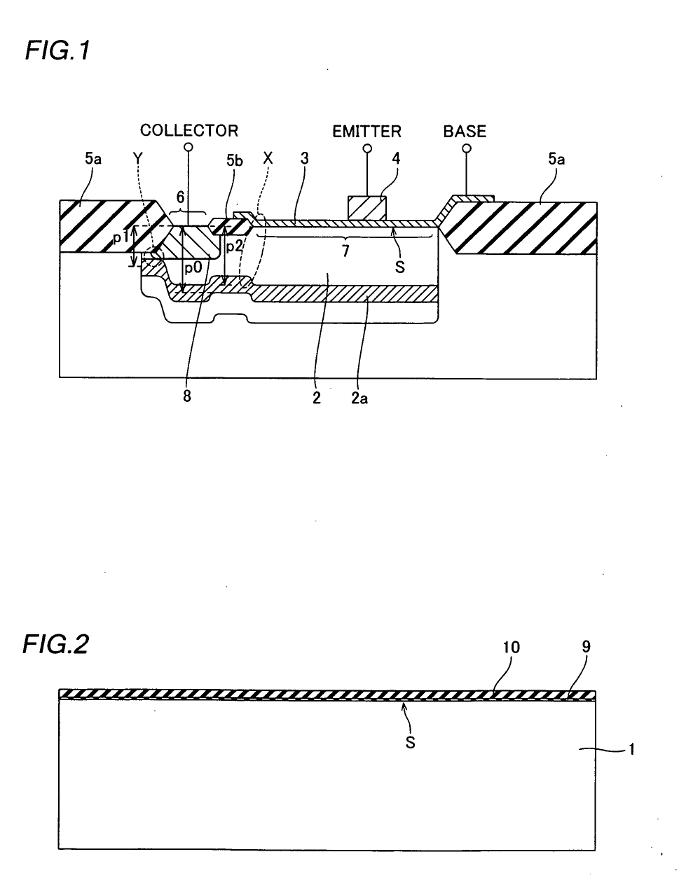

As shown in FIG. 1, a semiconductor device according to this embodiment is formed as an NPN junction transistor. This NPN junction transistor comprises a collector region 2 of an N-type conductive layer formed on a P-type silicon substrate 1 by ion implantation, a base region 3 of a P-type conductive layer formed on the collector region 2 and an emitter region 4 of the N-type conductive layer formed on the base region 3.

The collector region 2 contains an N-type impurity having a concentration distribution in a depth direction from a main surface S. A high concentration layer 2a having a particularly high concentration of the N-type impurity is formed around a position where the concentration of the N-type impurity reaches a peak. This high concentration layer 2a is a main conductive path inside the collector region 2 in emitter-collector conduction.

Element isolation layers made of silicon oxide film (COCOS oxide film) by a LOCOS method is formed on the main surface S of the P-type silicon substrate 1. The element isolation layers have a first insulating isolation film 5a comparting a prescribed active region, and a second insulating isolation film 5b having a thickness smaller than that of the first insulating isolation film 5a and separating an active region into two regions (the first active region 6 and the second active region 7). A bottom surface of the second insulating isolation film 5b is so formed as to be shallower than that of the first insulating isolation film 5a.

A collector pull-out portion 8 implanted with a high-concentration N-type impurity as an impurity layer is formed on the first active region 6, and the base region 3 and the emitter region 4 are formed on the second active region 7. A lower surface of the collector pull-out portion 8 is so formed as to be pushed out below those of the element isolation layers (the first insulating isolation film 5a and the second insulating isolation film 5b).

A collector electrode is electrically connected to the collector pull-out portion 8, while a base electrode is electrically connected to the base region 3. Additionally, an emitter electrode is electrically connected to the emitter region 4. Thus, a bipolar transistor (semiconductor device) is formed.

In the semiconductor device according to this embodiment, both of peak depths p1 and p2 located immediately under the first insulating isolation film 5a and the second insulating isolation film 5b are so formed as to be smaller than a peak depth p0 of each active region (the first active region 6 and the second active region 7). The peak depth p2 located immediately under the second insulating isolation film 5b is so formed as to be larger than the peak depth p1 located immediately under the first insulating isolation film 5a. The distribution position of the high concentration layer 2a in the collector region 2 varies in response to positions of the respective peak depths (peak depths p0 to p2).

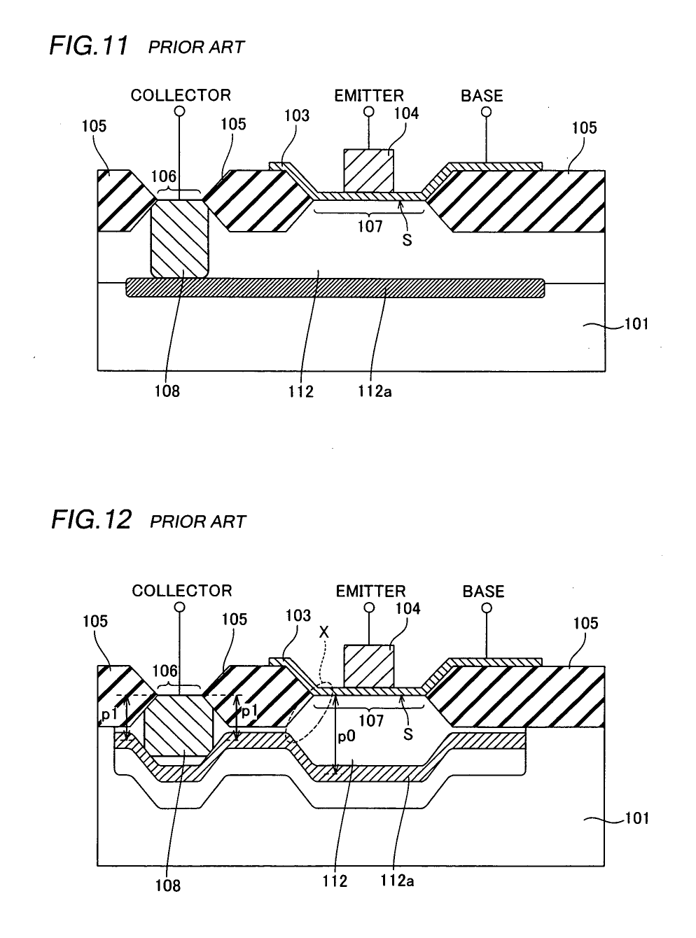

According to the aforementioned structure, the high concentration layer 2a shallowly distributing, located immediately under the first insulating isolation film 5a, and the collector pull-out portion 8 come closer to each other in the vicinity of the periphery of the collector pull-out portion 8 shown by a dotted lined circle Y in FIG. 1. Thus, the conductive resistance between the collector pull-out portion 8 and the high concentration layer 2a is kept low and a collector resistance can be reduced, as compared with a case where a portion corresponding to the high concentration layer 2a is provided at a constant depth position as the N-type buried layer 112a shown in FIG. 11.

On the other hand, the peak depth p2 located immediately under the second insulating isolation film 5b is deeper than the peak depth p1 located immediately under the first insulating isolation film 5a, whereby the junction capacitance between the collector and the base can be reduced while ensuring the breakdown voltage between the emitter and the collector and reducing the collector resistance on a side closer to the first insulating isolation film 5a, described above. The interval between the base region 3 and the high concentration layer 2a is increased in the vicinity of a side surface of the second insulating isolation film 5b (side closer to the second active region 7) shown by a dotted lined circle X in FIG. 1 as compared with a case where the peak depth located immediately under the second insulating isolation film 5b is the same as that located immediately under the first insulating isolation film 5a. In the semiconductor device according to this embodiment, therefore, increase in the parasitic capacitance between the collector and the base can be suppressed while reducing the collector resistance.

A process of fabricating a semiconductor device according to this embodiment will be now described.

As shown in FIG. 2, a thermal oxide film 9 is formed on the main surface S of the P-type silicon substrate 1 with a thickness of, for example, about 10 nm by thermal oxidation. A silicon nitride film 10 is formed on the thermal oxide film 9 with a thickness of, for example, about 100 nm by low pressure CVD (Chemical Vapor Deposition).

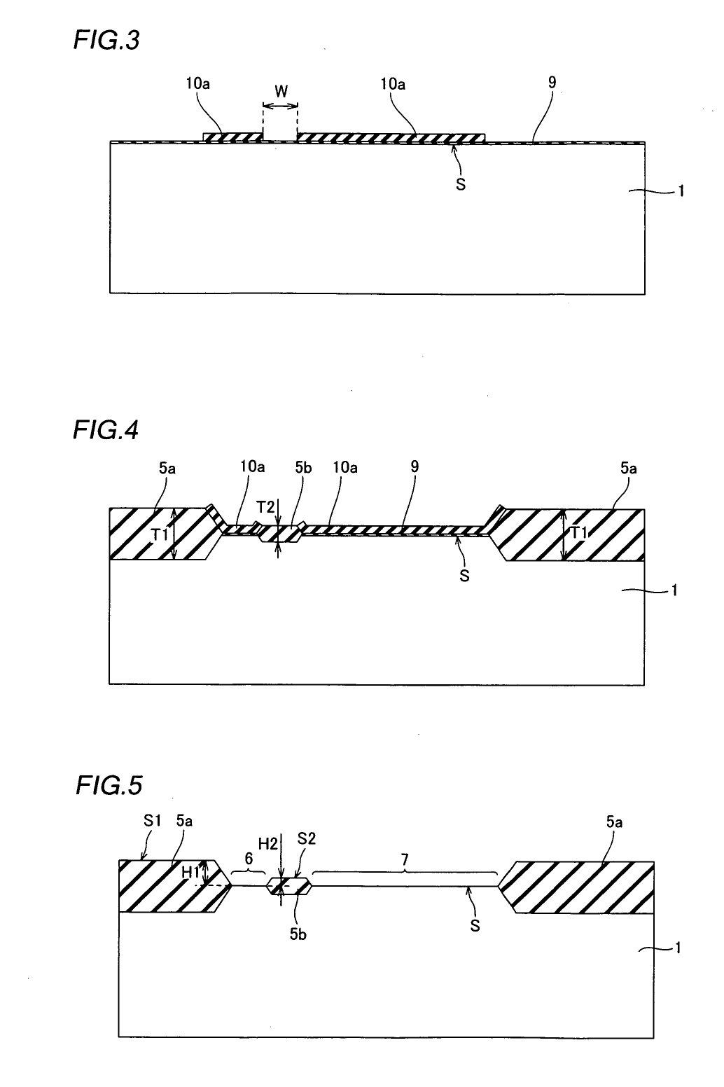

As shown in FIG. 3, resist masks (not shown) having prescribed patterns is provided by lithography and unnecessary portions of the silicon nitride film 10 are removed by dry etching. Thus, silicon nitride films 10a having prescribed patterns are so formed as to cover at least the active regions (see FIG. 1). The silicon nitride films 10a are each an example of the “mask layer” in the present invention. At this time, the opening width W of a portion (see FIG. 1) where the second insulating isolation film 5b is formed is set to at least about 400 nm smaller than that of the portion where the first insulating isolation film 5a is formed.

As shown in FIG. 4, oxidation is performed by thermal treatment at a temperature of about 1100° C. in an O₂ atmosphere and the element isolation layers made of SiO₂ is formed on the main surface S of the P-type silicon substrate 1 with a thickness of, for example, about 400 nm by LOCOS method. The element isolation layers include the first insulating isolation film 5a surrounding the prescribed active region and the second insulating isolation film 5b separating the active region into the two regions (the first active region 6 and the second active region 7). A thickness T1 of the first insulating isolation film 5a is formed with about 400 nm since the opening width of a region formed with no silicon nitride film 10a is sufficiently wide, while a thickness T2 of the second insulating isolation film 5b is formed with a thickness of about 240 nm since the opening width W of a region with no silicon nitride film 10a is shallow, about 400 nm due to suppression of oxidation. In other words, the opening widths of openings of the regions formed with no silicon nitride films 10a, where the first insulating isolation film 5a and the second insulating isolation film 5b are formed, is set such that the first insulating isolation film 5a is formed to have a thickness smaller than that of the second insulating isolation film 5b by thermally oxidizing the surface of the P-type silicon substrate 1.

As shown in FIG. 5, the silicon nitride films 10a are removed by dilute hydrofluoric acid and phosphoric acid. Then, a portion corresponding to the thermal oxide film 9 is removed by dilute hydrofluoric acid. Thus, the first insulating isolation film 5a surrounding the prescribed active region for compartment and the second insulating isolation film 5b having the thickness smaller than that of the first insulating isolation film 5a and separating the active region into the two regions (the first active region 6 and the second active region 7) are formed as the element isolation layers by the LOCOS method on the main surface S of the P-type silicon substrate 1. The element isolation layers by the LOCOS method are formed to partially protrude upward from the main surface S of the P-type silicon substrate 1. Specifically, in the first insulating isolation film 5a, a surface S1 of the first insulating isolation film 5a is protrude from the main surface S by a height H1, while a surface S2 of the second insulating isolation film 5b protrudes from the main surface S by a height H2.

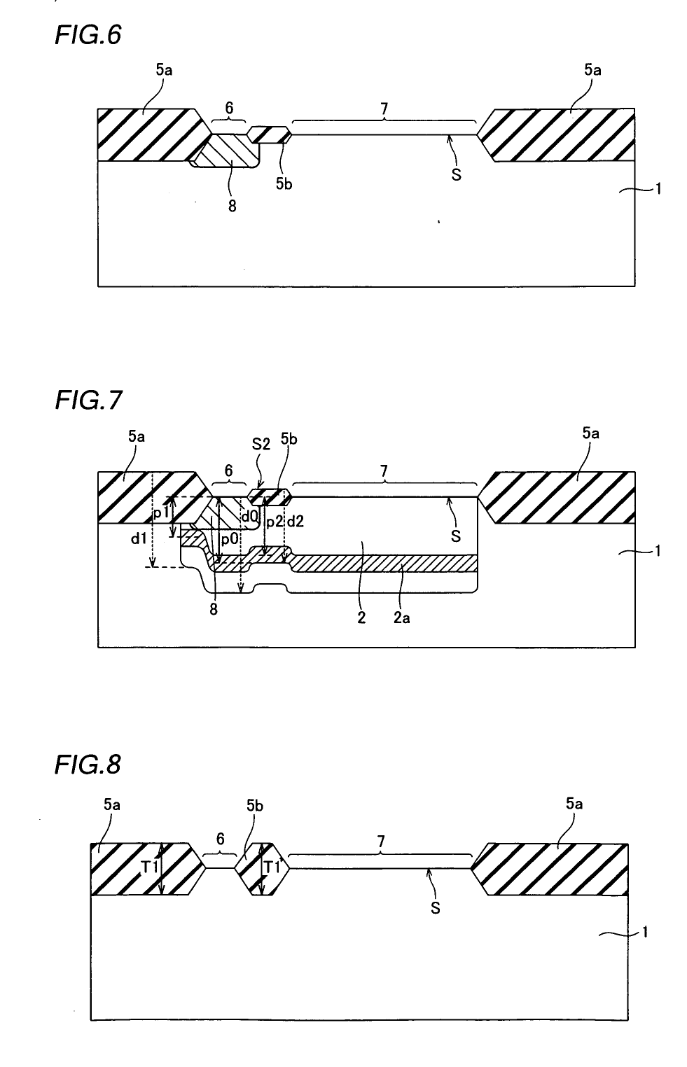

As shown in FIG. 6, resist masks (not shown) are provided on portions of the P-type silicon substrate 1 other than the first active region 6 for ion-implanting an N-type impurity. Thereafter activation-is performed by thermal treatment, thereby forming an impurity layer (high-concentration N-type conductive layer) employed as the collector pull-out portion 8 on the first active region 6. Phosphorus (P) is implanted under ion implantation conditions of an acceleration voltage of about 100 kV and a dose of about 3×10¹⁵ cm⁻². A thermal treatment condition is performed at about 950° C. in an nitrogen (N₂) atmosphere for two hours, for example. Thus, the lower surface of the collector pull-out portion 8 is so formed as to push out below the lower surface of the element isolation layer (particularly the first insulating isolation film 5a).

As shown in FIG. 7, resist masks (not shown) are provided on portions except the collector region 2 on the P-type silicon substrate 1 for ion-implanting the N-type impurity. Thereafter activation is performed by thermal treatment, for forming the N-type conductive layer employed as the collector region 2 (high concentration layer 2a). Phosphorus (P) employed as the N-type impurity is implanted under ion implantation conditions of an acceleration voltage of about 700 kV and a dose of about 1×10¹⁴ cm⁻² while being inclined from a direction perpendicular to the main surface S by an angle 7°, for example. A thermal treatment condition is performed at about 950° C. in an nitrogen (N₂) atmosphere for thirty minutes, for example. In the implantation conditions, ions evenly collide with atoms in the substrate, and hence the N-type impurity is implanted from the implantation surface of the P-type silicon substrate 1 to a constant depth. Thus, the N-type impurity is implanted from the surface S1 of the first insulating isolation film 5a, the surface S2 of the second insulating isolation film 5b and the main surface S of the active region (the first active region 6 and the second active region 7) to depths d0, d1, and d2 respectively. Thus, both of the peak depths p1 and p2 located immediately under the first and second insulating isolation films 5a and 5b are shallower than the peak depth p0 located immediately under the active region (the first active region 6 and the second active region 7). The peak depth p2 located immediately under the second insulating isolation film 5b is deeper than the peak depth p1 located immediately under the first insulating isolation film 5a. The distribution position of the high concentration layer 2a in the collector region 2 corresponds to the respective peak depths (peak depths p0 to p2).

Finally, the base region 3 of the P-type conductive layer is formed on the second active region 7, and the emitter region 4 of the N-type conductive layer is formed on the base region 3 as shown in FIG. 1. The collector electrode, the base electrode and the emitter electrode are electrically connected to the collector pull-out portion 8, the base region 3 and the emitter region 4 respectively, whereby the bipolar transistor (semiconductor device) according to this embodiment can be fabricated.

According to the semiconductor device of this embodiment and the method of fabricating the same, the following effects can be obtained.

According to this embodiment, as hereinabove described, the peak depth p2 located immediately under the second insulating isolation film 5b provided between the first active region 6 and the second active region 7 is deeper than the peak depth p1 located immediately under the first insulating isolation film 5a, whereby the interval between the base region 3 and the high concentration layer 2a is increased in the vicinity of the side surface of the second insulating isolation film 5b (side closer to the second active region 7) as compared with the case where the peak depth located immediately under the second insulating isolation film 5b is the same as that located immediately under the first insulating isolation film 5a and hence the parasitic capacitance (junction capacitance) between the collector and the base can be reduced.

According to this embodiment, as hereinabove described, the peak depth p1 located immediately under the first insulating isolation film 5a is shallower than the peak depth p0 located immediately under the active region (the first active region 6 and the second active region 7), whereby the high concentration layer 2a shallowly formed, located immediately under the first insulating isolation film 5a, and the collector pull-out portion 8 come closer to each other in the vicinity of the periphery of the collector pull-out portion 8. Thus, the conductive resistance between the collector pull-out portion 8 and the high concentration layer 2a is kept low as compared with the case where the peach depths located immediately under the second active region 7 and the first insulating isolation film 5a are equal to each other and a collector resistance can be reduced. Therefore, increase in the parasitic capacitance between the collector and the base can be suppressed while reducing the collector resistance.

According to this embodiment, as hereinabove described, the collector region 2 is formed by employing ion implantation, whereby a manufacturing cost can be suppressed as compared with a conventional case of forming the same by epitaxial technique, and the cost of the semiconductor device can be reduced.

According to this embodiment, as hereinabove described, the thickness (thickness T2) of the second insulating isolation film 5b provided between the first active region 6 and the second active region 7 is selectively formed so as to be smaller than that of the first insulating isolation film 5a when forming the collector region 2 by ion implantation, whereby the peak depths located immediately under these are changed. Thus, the aforementioned bipolar transistor (semiconductor device) capable of suppressing increase in the parasitic capacitance between the collector and the base can be easily fabricated while reducing the aforementioned collector resistance.

Although the present invention has been described and illustrated in detail, it is clearly understood that the same is by way of illustration and example only and is not to be taken by way of limitation, the spirit and scope of the present invention being limited only by the terms of the appended claims.

While the second insulating isolation film 5b having a thickness smaller than that of the first insulating isolation film 5a is formed by employing the silicon nitride films 10a having the opening with the opening width W (about 400 nm) on the region corresponding to the second insulating isolation film 5b in the step shown in FIG. 4 in the aforementioned embodiment, the present invention is not restricted to this. For example, the second insulating isolation film may be alternatively formed by employing a silicon nitride film provided with two or more similar openings each having the opening width W. The interval between the adjacent openings may be designed to be smaller and bird's beak portions may be coupled after thermal oxidation so that the adjacent insulating isolation films function as one insulating isolation film. Also in these cases, the aforementioned effects can be enjoyed.

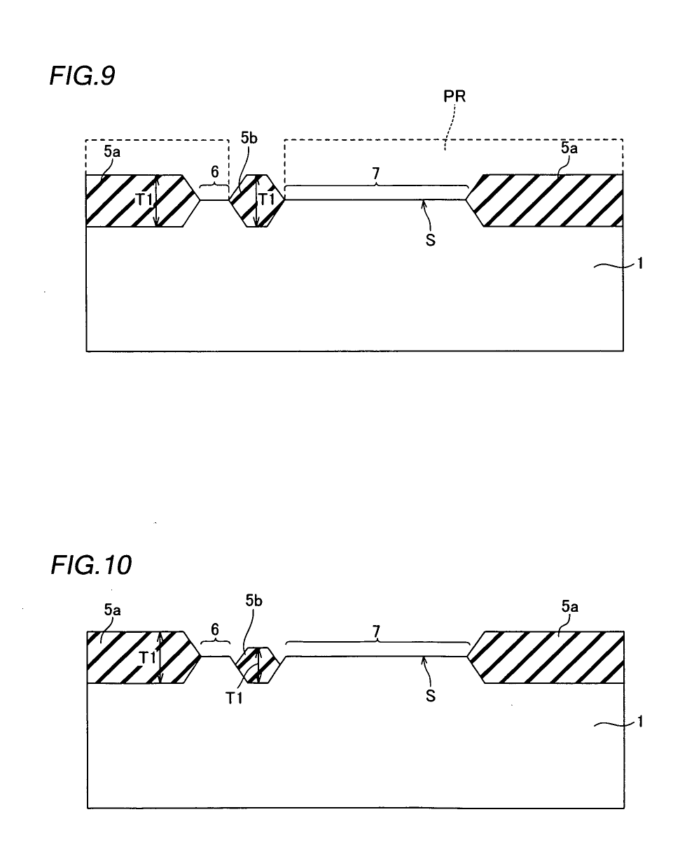

While the opening width W of the silicon nitride films 10a is set to about 400 nm, shallower than the portion where the first insulating isolation film 5a is formed in the step illustrated in FIG. 4, as a method of reducing the thickness of the second insulating isolation film 5b provided between the first active region 6 and the second active region 7 in the aforementioned embodiment, the present invention is not restricted to this. As shown in FIGS. 8 to 10, the second insulating isolation film 5b may be so formed as to have the same thickness as that of the first insulating isolation film 5a and thereafter resist masks PR may be provided on portions other than the second insulating isolation film 5b and the second insulating isolation film 5b may be selectively partially removed by etching for reducing the thickness, for example.

Resist masks may be provided on the portions other than the first insulating isolation film 5a, an impurity such as arsenic (As) or phosphorus (P) may be implanted into the P-type silicon substrate 1 fabricated through the step illustrated in FIG. 3, and the element isolation layer (the first insulating isolation film 5a and the second insulating isolation film 5b) may be formed by thermal oxidation as illustrated in FIG. 4 after removing the resist masks. Thus, the oxidation rate on the region (corresponding to the first insulating isolation film 5a) into which the impurity is implanted is increased and hence the thickness thereof is relatively increased as compared with that of the region (corresponding to the second insulating isolation film 5b) into which no impurity is implanted. Consequently, the thickness of the second insulating isolation film 5b can be reduced as compared with that of the first insulating isolation film 5a.

Resist masks may be provided on the portions other than the second insulating isolation film 5b, an impurity such as nitrogen (N₂) may be implanted into the P-type silicon substrate 1 fabricated through the step illustrated in FIG. 3, and the element isolation layer (the first insulating isolation film 5a and the second insulating isolation film 5b) may be formed by thermal oxidation as illustrated in FIG. 4 after removing the resist masks. In this case, oxidation on the region (corresponding to the second insulating isolation film 5b) into which the nitrogen (N₂) impurity is implanted is suppressed and can be so formed as to have the thickness relatively smaller than that of the region (corresponding to the first insulating isolation film 5a) into which no impurity is implanted.

The effects capable of suppressing increase in the parasitic capacitance between the collector and the base can be enjoyed while reducing the aforementioned collector resistance also when the thickness of the second insulating isolation film 5b is reduced as compared with that of the first insulating isolation film 5a by each of the aforementioned method.

While the N-type impurity is implanted at an inclined angle of 7° in the aforementioned embodiment, the present invention is not restricted to this. For example, the N-type impurity is implanted at an angle perpendicular to the main surface S of the P-type silicon substrate 1.

When the N-type impurity is vertically implanted, the peak depths located immediately under the element isolation layer and the active region further vary with difference of the natures of constitutive substances. More specifically, channeling phenomenon (phenomenon that a part of ions hardly collide with atoms and penetrate up to a deep portion of the substrate in ion implantation) occurs on the active region and the N-type impurity is added to a deeper portion of the P-type silicon substrate 1. On the regions where the element isolation layers are formed, on the other hand, the channeling phenomenon does not occur during ions penetrate the element isolation layer, and the depth on the region where the N-type impurity is formed is shallow. Therefore, when the peak depth of the N-type impurity located immediately under the active region is similarly designed, the peak depth located immediately under the element isolation layer is formed so as to be further shallower and hence increase in the parasitic capacitance (junction capacitance) between the collector and the base becomes a serious problem.

The thickness (thickness T2) of the second insulating isolation film 5b provided between the first active region 6 and the second active region 7 as in the present invention is formed as to be smaller than that (thickness T1) of the first insulating isolation film 5a and then ion implantation is vertically performed, whereby the channeling phenomenon occurs earlier on the region where the second insulating isolation film 5b is formed after ion penetration and hence the depth of the region where the N-type impurity is formed can be made deeper than the region where the first insulating isolation film 5a is formed by the difference of the thicknesses. Thus the aforementioned effect can be similarly enjoyed.

According to the aforementioned embodiment, while the present invention is applied to the semiconductor device comprising the NPN junction transistor, the present invention is not restricted to this. For example, the present invention is similarly applicable for a PNP junction transistor having a collector region made of a P-type conductive layer, a base region made of an N-type conductive layer and an emitter region made of the P-type conductive layer. For example, the present invention is also applicable for a bipolar transistor such as a silicon germanium (SiGe) heterojunction bipolar transistor so far as a bipolar transistor having an element isolation layer.

What is claimed is:

1. A semiconductor device comprising:
a first insulating isolation film provided on a main surface of a semiconductor substrate;
an active region surrounded by said first insulating isolation film;
a second insulating isolation film provided on said main surface of said semiconductor substrate, having a thickness smaller than that of said first insulating isolation film and separating said active region into a first active region and a second active region;
an impurity layer formed on said first active region;
a base region formed on said second active region and an emitter region on said base region; and
a collector region formed on said semiconductor substrate.

2. A semiconductor device according to claim 1, wherein
the depth of a position where an impurity concentration reaches a peak from the main surface, located immediately under said second insulating isolation film of said collector region is larger than that located immediately under said first insulating isolation film.

3. A semiconductor device according to claim 1, wherein
the height of said second insulating isolation film from said main surface of said semiconductor substrate is smaller than the height of said first insulating isolation film from said main surface of said main surface.

4. A semiconductor device according to claim 3, wherein
the depth of a bottom surface of said second insulating isolation film is substantially equal to the depth of a bottom surface of said first insulating isolation film.

5. A semiconductor device according to claim 1, wherein
the depth of a position where an impurity concentration reaches a peak from the main surface, located immediately under said first insulating isolation film is smaller than that located immediately under said active region.

6. A semiconductor device according to claim 1, wherein
said collector region is formed by implanting ions into said semiconductor substrate provided with said first insulating isolation film and said second insulating isolation film.

7. A semiconductor device according to claim 1, wherein
said first insulating isolation film and said second insulating isolation film are LOCOS oxide films.

8. A semiconductor device according to claim 1, wherein
a bottom surface of said second insulating isolation film is shallower than a bottom surface of said first insulating isolation film.

9. A method of fabricating a semiconductor device, comprising steps of:
forming a first insulating isolation film comparting an active region and a second insulating isolation film having a thickness smaller than that of said first insulating isolation film and separating said active region into a first active region and a second active region on a main surface of a semiconductor substrate;
forming a collector region by implanting ions into said semiconductor substrate formed with said first insulating isolation film and said second insulating isolation film;
forming an impurity layer on said first active region; and
forming a base region on said second active region and an emitter region on said base region.

10. A method of fabricating a semiconductor device according to claim 9, wherein
said step of forming said second insulating isolation film includes a step of forming such that the height of said second insulating isolation film from said main surface of said semiconductor substrate is smaller than the height of said first insulating isolation film from said main surface of said semiconductor substrate.

11. A method of fabricating a semiconductor device according to claim 9, wherein
said step of forming said second insulating isolation film includes a step of forming said second insulating isolation film so as to have the same thickness as that of said first insulating isolation film and thereafter selectively reducing the thickness by etching.

12. A method of fabricating a semiconductor device according to claim 9, wherein
said step of forming said first insulating isolation film and said second insulating isolation film includes steps of:
forming mask layers on said main surface of said semiconductor substrate and thereafter exposing surfaces of said semiconductor substrate by forming a first opening and a second opening on portions of said mask layer, where said first insulating isolation film and said second insulating isolation film are formed, and
employing said mask layers as masks for thermally oxidizing portions of said first opening and said second opening, where the surfaces of said semiconductor substrate are exposed to thereby form said first insulating isolation film and said second insulating isolation film, and
the widths of said first opening and said second opening are set such that the thickness of said second insulating isolation film is so formed as to be smaller than that of said first insulating isolation film by thermally oxidizing the surfaces of said semiconductor substrate.

13. A method of fabricating a semiconductor device according to claim 9, wherein
said step of forming said first insulating isolation film and said second insulating isolation film includes a step of forming said first insulating isolation film and said second insulating isolation film by a LOCOS method.

14. A method of fabricating a semiconductor device according to claim 9, wherein
said step of forming said first insulating isolation film and said second insulating isolation film includes a step of forming such that a bottom surface of said second insulating isolation film is shallower than a bottom surface of said first insulating isolation film.

15. A method of fabricating a semiconductor device according to claim 9, wherein
said step of forming said first insulating isolation film includes a step of ion-implanting arsenic or phosphorus into the main surface of said semiconductor substrate formed with said first insulating isolation film and thereafter forming said first insulating isolation film by thermal oxidation.

16. A method of fabricating a semiconductor device according to claim 9, wherein
said step of forming said second insulating isolation film includes a step of ion-implanting nitrogen into the main surface of said semiconductor substrate formed with said second insulating isolation film and thereafter forming said first insulating isolation film by thermal oxidation.

17. A method of fabricating a semiconductor device according to claim 9, wherein
said step of forming said first insulating isolation film and said second insulating isolation film includes a step of simultaneously forming said first insulating isolation film and said second insulating isolation film and forming such that the thickness of said second insulating isolation film is smaller than that of said first insulating isolation film.
